(19) United States
(12) Patent Application Publication
(10) Pub. No.: US 2012/0319289 A1
(43) Pub. Date: Dec. 20, 2012

(54) SEMICONDUCTOR PACKAGE

(75) Inventors: Kenichi MORI, Nagano (JP); Hideaki SAKAGUCHI, Nagano (JP)

(73) Assignee: SHINKO ELECTRIC INDUSTRIES CO., LTD., Nagano (JP)

(21) Appl. No.: 13/493,036

(22) Filed: Jun. 11, 2012

(30) Foreign Application Priority Data
Jun. 16, 2011 (JP) 2011-134291

(51) Int. Cl. H01L 23/48

(52) U.S. Cl. 257/773; 257/E23.01

(57) ABSTRACT

A semiconductor package includes a semiconductor chip having plural electrode pads, and a wiring substrate having plural electrode pads to mount the semiconductor chip on the wiring substrate, wherein the plural electrode pads of the semiconductor chip include a first electrode pad, and a second electrode pad arranged on an outer periphery side of the first electrode pad, the plural electrode pads of the wiring substrate include a third electrode pad, and a fourth electrode pad arranged on an outer periphery side of the third electrode pad, the first electrode pad and the third electrode pad are connected via a first connecting portion, and the second electrode pad and the fourth electrode pad are connected via a second connecting portion including a pin.

### CROSS-REFERENCE TO RELATED APPLICATION

This patent application is based upon and claims the benefit of priority of the prior Japanese Patent Application No. 2011-134291 filed on Jun. 16, 2011, the entire contents of which are incorporated herein by reference.

### FIELD

The embodiments discussed herein are related to a semiconductor package formed by installing a semiconductor chip on a wiring substrate.

### BACKGROUND

Japanese Laid-open Patent Publication No. 03-217024 discloses a semiconductor package formed by mounting a semiconductor chip on a wiring substrate. For example, the wiring substrate is formed by alternately laminating plural wiring layers and plural insulating layers on a substrate body made of silicon and by connecting neighbor wiring layers via the insulating layer with a via hole penetrating through the insulating layer sandwiched between the neighbor wiring layers.

For example, in this semiconductor package, the outermost layer of the wiring substrate has an electrode pad, and the electrode pad is electrically connected to an electrode pad of a semiconductor chip.

The manufacturing process of the semiconductor package includes putting the wiring substrate, which has the semiconductor chip formed via solder balls, in a reflow furnace, heating the solder balls, or the like and melting the solder balls, and electrically connecting the electrode pads of the wiring substrate to the electrode pads of the semiconductor chip via the solder balls or the like.

However, the main material of the semiconductor chip is ordinarily silicon, the main material of an insulating layer of the wiring substrate may be a resin, and the insulating layer of the wiring substrate frequently contains a filler. The thermal expansion coefficient of silicon is about 3 ppm/° C. The thermal expansion coefficient of the insulating layer of the wiring substrate is about several tens ppm/° C. depending on the resin, the material of the filler, the contained amount of the filler or the like. Therefore, if the wiring substrate and the semiconductor chip mounted on the wiring substrate via the solder ball or the like are heated in the reflow furnace and then cooled, displacement such as warpage and transformation may occur in the wiring substrate having a high thermal expansion coefficient. As a result, a crack or hiatus occurs in the solder ball or the like by stress caused by the displacement. Especially, great stress is apt to be applied to the outer peripheral side of the wiring layer to thereby displace the outer peripheral side of the wiring substrate. Therefore, the solder balls or the like arranged on the outer periphery side of the wiring substrate or the like may frequently form cracks or hiatuses.

### SUMMARY

According to an aspect of the embodiment, a semiconductor package includes a semiconductor chip having a plurality of electrode pads, and a wiring substrate having a plurality of electrode pads to mount the semiconductor chip on the wiring substrate, wherein the plurality of electrode pads of the semiconductor chip include a first electrode pad, and a second electrode pad arranged on an outer periphery side of the first electrode pad, wherein the plurality of electrode pads of the wiring substrate include a third electrode pad, and a fourth electrode pad arranged on an outer periphery side of the third electrode pad, wherein the first electrode pad and the third electrode pad are connected via a first connecting portion, wherein the second electrode pad and the fourth electrode pad are connected via a second connecting portion including a pin.

The object and advantages of the invention will be realized and attained by means of the elements and combinations particularly pointed out in the appended claims.

It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view of a semiconductor package of a first embodiment;

FIG. 2 is a plan view of electrode pads of a semiconductor chip and electrode pads of a wiring substrate;

FIG. 3 is a cross-sectional view of a semiconductor package of a modified example 1 of the first embodiment;

FIG. 4 illustrates a manufacturing process of a semiconductor package of a modified example 2 of the first embodiment;

FIG. 5 illustrates the manufacturing process of the semiconductor package of the modified example 2 of the first embodiment;

FIG. 6 illustrates the manufacturing process of the semiconductor package of the modified example 2 of the first embodiment;

FIG. 7 illustrates a state in which a connecting unit follows displacement caused on an outer periphery side of the wiring substrate;

FIG. 8 is a plan view of electrode pads of another semiconductor chip and electrode pads of another wiring substrate;

FIG. 9 is a plan view of electrode pads of another semiconductor chip and electrode pads of another wiring substrate; and

FIG. 10 is a plan view of electrode pads of another semiconductor chip and electrode pads of another wiring substrate.

### DESCRIPTION OF EMBODIMENTS

Preferred embodiments of the present invention will be described with reference to accompanying drawings. The same reference symbols may be provided for the corresponding portions in the figures and description of these portions may be omitted.

### [a] First Embodiment

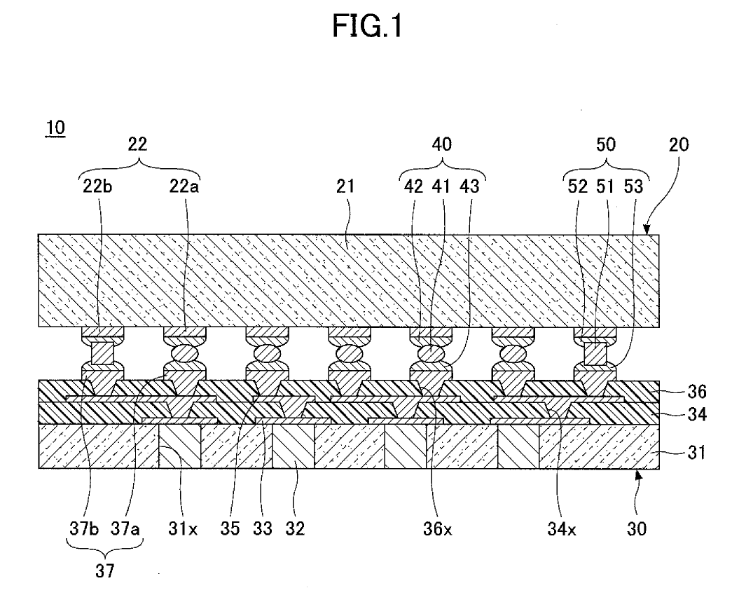

FIG. 1 is a cross-sectional view of the semiconductor package of the first embodiment.

Referring to a semiconductor package 10 illustrated in FIG. 1, a semiconductor chip 20 is mounted on a wiring substrate 30 via connecting units 40 and 50.

The semiconductor chip 20 includes a main body 21 and electrode pads 22. The main body 21 is formed by providing a semiconductor integrated circuit (not illustrated) on a semiconductor substrate (not illustrated) which is thinned and made of silicon or the like. Plural electrode pads 22 including first electrode pads 22a and second electrode pads 22b are formed below the main body 21. The first electrode pads 22a and the second electrode pads 22b are electrically connected to the semiconductor integrated circuit (not illustrated).

The first and second electrode pads 22a and 22b may be formed by laminating an Under Bump Metal (UBM) layer on aluminum. An exemplary UBM layer may be formed by laminating titanium (Ti) and copper (Cu) in this order or laminating nickel (Ni) and gold (Au) in this order. The UBM layers have functions of improving contact between the first electrode pad 22a and the first connector 42 and contact between the second electrode pad 22b and a third connector 52.

The first electrode pad 22a does not contact a pin 51 while the second electrode pad 22b contacts the pin 51. For convenience, although the first electrode pad 22a and the second electrode pad 22b are distinguished by their reference symbols, the materials, the shapes, the forming methods or the like may be the same between the first electrode pad 22a and the second electrode pad 22b.

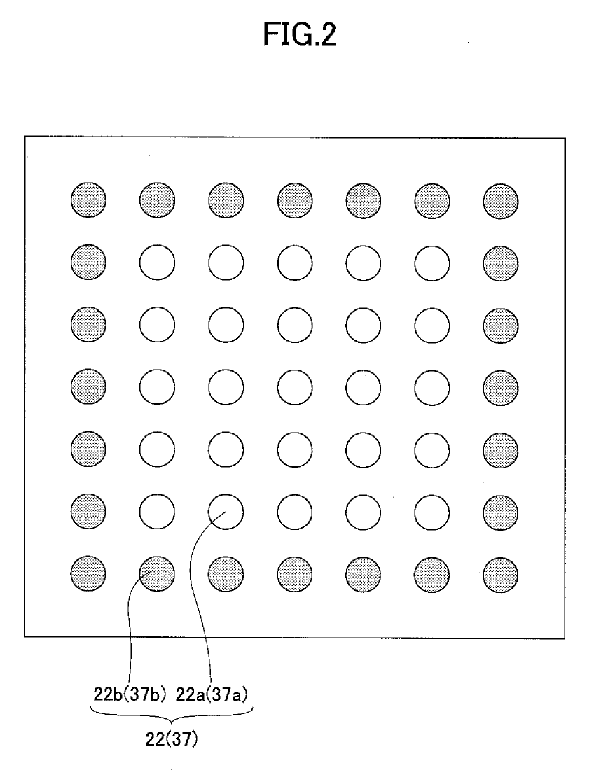

FIG. 2 is a plan view of the electrode pads 22 of the semiconductor chip 20 and the electrode pads 37 of the wiring substrate 30. Referring to FIG. 2, the semiconductor chip 20 and the wiring substrate 30 are rectangular in their plan views. FIG. 2 illustrates the semiconductor chip viewed from a surface of the semiconductor chip on which the electrode pads 22 are formed, and FIG. 2 also illustrates the wiring substrate viewed from a surface of the wiring substrate on which the electrode pads 37 are formed. Referring to FIG. 2, the second electrode pads 22b and fourth electrode pads 37b are shaded like a satin finished surface for convenience.

Referring to FIG. 2, the shapes of the first and second electrode pads 22a and 22b are substantially circular. The first and second electrode pads 22a and 22b are arranged so as to be patterned like an area array. The second electrode pads 22b are arranged in an outermost periphery of the plural electrode pads 22 so as to surround the first electrode pads 22a. The diameters of the first and second electrode pads 22a and 22b are about 30 to 800 μm. The third and fourth electrode pads 37a and 37b have diameters of about 30 to 300 μm.

Referring back to FIG. 1, the wiring substrate 30 includes a substrate body 31, a first wiring layer 33, a first insulating layer 34, a second wiring layer 35, a second insulating layer 36, and a third wiring layer 37.

The substrate body 31 is a base substance for forming the first wiring layer 33 or the like. Though holes 31x are formed in the substrate body 31. For example, the thickness of the substrate body 31 may be about 200 to 400 μm. The material of the substrate body 31 is silicon, glass, ceramic, resin or the like.

The through hole 31x is substantially circular in its plan view. The through hole 31x penetrates from a first surface of the substrate body 31 to a second surface of the substrate body 31. The diameter of the through hole 31x is, for example, about 40 to 60 μm. A conductive body is supplied inside the through hole 31x to thereby form a through electrode 32. The material of the through electrode 32 is, for example, copper (Cu) or the like. One end portion of the through electrode 32 is exposed from the first surface of the substrate body 31 and substantially arranged on the first surface of the substrate body 31. The other end portion of the through electrode 32 is exposed from the second surface of the substrate body 31 and substantially arranged on the second surface of the substrate body 31.

The other end portion of the through electrode 32 functions as an electrode pad electrically connected to a mounting board (not illustrated) such as a motherboard. When necessary, a metallic layer may be formed on the other end portion of the through electrode 32 in order to improve connection reliability. An example of the metallic layer is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like.

If the material of the substrate body 31 is silicon, an insulating layer made of silicon dioxide, silicon nitride or the like is formed on the first surface and the second surface of the substrate body 31 and on inner side surfaces of the through holes 31x. If the material of the substrate body 31 is an insulating material such as glass, the insulating layer is preferably not formed.

The first wiring layer 33 is formed on the first surface of the substrate body 31 and patterned to have a predetermined planar shape. The first wiring layer 33 is electrically connected to the through electrodes 32. For example, the material of the first wiring layer 33 may be copper (Cu) or the like. The thicknesses of the first wiring layer 33 may be about 10 to 20 μm.

The first insulating layer 34 is formed on the first surface of the substrate body 31 so as to cover the first wiring layer 33. The material of the first insulating layer 34 may be a thermosetting insulating resin or the like containing an epoxy resin as a main material. The thickness of the first insulating layer 34 may be about 15 to 35 μm. The first insulating layer 34 may contain a filler such as silica (SiO₂).

The second wiring layer 35 includes via wirings which penetrate through the first insulating layer 34 and are supplied inside first via holes 34x, from which the upper surface of the first wiring layer 33 is exposed, and a wiring pattern formed on the first insulating layer 34. The first via hole 34x is opened on the side of the second insulating layer 36 and the bottom surface of the first via hole 34x is formed by the upper surface of the first wiring layer 33. The area of the opening portion of the first via hole 34x on the side of the second insulating layer 36 is greater than the area of the bottom surface so that the first via hole 34x becomes a recess in a shape of a truncated cone. The via wiring is formed inside the recess. The via wiring is a through wiring penetrating through the insulating layer to thereby mutually connect the pertinent wiring layers.

The second wiring layer 35 is electrically connected to the first wiring layer 33 exposed toward the bottom portions of the first via holes 34x. For example, the material of the second wiring layer 35 may be copper (Cu) or the like. For example, the thickness of the second wiring layer 35 may be about 10 to 20 μm.

The second insulating layer 36 is formed to cover the second wiring layer 35 on the first insulating layer 34. The material of the second insulating layer 36 may be an insulating resin similar to that of the first insulating layer 34. The thickness of the second insulating layer 36 may be about 15 to 35 μm. The second insulating layer 36 may contain a filler made of silica (SiO₂) or the like.

The third wiring layer 37 includes via wirings which penetrate through the second insulating layer 36 and are supplied inside second via holes 36x, from which the upper surface of the second wiring layer 35 is exposed, and electrode pads formed on the second insulating layer 36. The second via hole 36x is opened on the side of the semiconductor chip 20 and the bottom surface of the second via hole 36x is formed by the upper surface of the second wiring layer 35. The area of the opening portion of the second via hole 36x on the side of the semiconductor chip 20 is greater than the area of the bottom surface of the second via hole 36x so that the second via hole 36x becomes a recess in a shape of a truncated cone. The via wiring is formed inside the recess. The via wiring is a through wiring penetrating through the insulating layer to thereby mutually connect the pertinent wiring layers.

The third wiring layer 37 is electrically connected to the second wiring layer 35 exposed on the bottom portion of the second via holes 36x. For example, the material of the third wiring layer 37 may be copper (Cu) or the like. For example, the thickness of the third wiring layer 37 may be about 10 to 20 μm.

The third wiring layer 37 includes the third and fourth electrode pads 37a and 37b. Referring to FIG. 2, the shapes of the third and fourth electrode pads 37a and 37b are substantially circular. The third and fourth electrode pads 37a and 37b are arranged so as to be patterned like an area array. The number of the third electrode pad 37a may be plural, and the number of the fourth electrode pad 37b may be plural. The fourth electrode pads 37b are arranged along an outermost periphery of the third wiring layer 37 so as to surround the third electrode pads 37a. The third electrode pad 37a does not contact the pin 51 and the fourth electrode pad 37b contacts the pin 51. For convenience, although the third electrode pad 37a and the fourth electrode pad 37b are distinguished by their reference symbols, the materials, the shapes, the forming methods or the like may be the same between the third electrode pad 37a and the fourth electrode pad 37b.

Within the first embodiment, the third and fourth electrode pads 37a and 37b in substantially circular shapes are arranged so as to be patterned like the area array. However, the third wiring layer 37 may be patterned to be in a predetermined planar shape and a solder resist layer having an opening portion in a shape of area array may be provided. The third electrode pad 37a and the first electrode pad 22a of the semiconductor chip are positioned so as to substantially overlap in the plan view of the semiconductor package 10. The fourth electrode pad 37b and the second electrode pad 22b of the semiconductor chip are positioned so as to substantially overlap in the plan view of the semiconductor package 10.

The third electrode pad 37a is electrically connected to the first electrode pad 22a of the semiconductor chip 20 via the connecting unit 40. The connecting unit 40 includes a conductive ball 41, a first connector 42 and a second connector 43. The conductive ball 41 is, for example, a solder ball, a copper core ball formed by covering a periphery of a copper core by solder, a resin core ball formed by covering a periphery of a resin core by solder, or the like. The solder material contained in the conductive ball 41 is, for example, Sn—Ag, Sn—Sb, Sn-90Pb, Sn—Cu or the like. For example, materials of the first and second connectors 42 and 43 are similar to a solder material contained in the conductive ball 41.

The conductive ball 41 is substantially like a sphere before reflow. After the reflow, the conductive ball is vertically deformed to be in a substantially ellipse shape in its cross-sectional view. The preferable major axis in the planar directions of the conductive ball 41 and the preferable minor axis in the height directions differ depending on a pitch of the conductive balls 41. When the conductive balls 41 are arranged at a pitch of 1 mm, it is preferable to determine the length of the major axis to be about 800 μm and to determine the length of the minor axis to be about 500 μm. When the conductive balls 41 are arranged at a pitch of 0.5 mm, it is preferable to determine the length of the major axis to be about 300 μm and to determine the length of the minor axis to be about 200 μm. When the conductive balls 41 are arranged at a pitch of 0.2 mm, it is preferable to determine the length of the major axis to be about 150 μm and to determine the length of the minor axis to be about 100 μm. The lengths are only for example and are not limited to the above values.

Referring to FIG. 1, a border between the conductive ball 41 and the first connector 42 and a border between the conductive ball 41 and the second connector 43 are clearly illustrated. Practically, because the solder material contained in the conductive ball 41, the first connector 42 and the second connector 43 are molten and alloyed, the border may not be clearly distinguished as illustrated in FIG. 1.

The fourth electrode pad 37b is electrically connected to the second electrode pad 22b of the semiconductor chip 20 via the connecting unit 50. The connecting unit 50 includes the pin 51, a third connector 52, and a fourth connector 53. One end of the pin 51 is joined to the second electrode pad 22b via the third connector 52. The other end of the pin 51 is connected to the fourth electrode pad 37b via the fourth connector 53.

The pin 51 is provided to relax a stress applied to an outer periphery of the wiring substrate 30 by connecting the third connector 52 and the fourth connector 53 with the second electrode pad 22b and the fourth electrode pad 37b, respectively. The shape of the pin 51 is not limited as long as the above function is obtainable. For example, the shape of the pin 51 may be like a circular cylinder, a six-sided prism or the like. For example, when the pin 51 is shaped like a circular cylinder, the diameter of the circular cylinder is about 30 to 300 μm. For example, the height of the pin 51 is about 50 to 500 μm. The height of the pin 51 is preferably about the length of the minor axis of the conductive ball 41 in the height direction.

The pin 51 may be made of a conductive material or an insulating material. Within the first embodiment, the pin 51 is made of a conductive material and the pin 51 is used as a part of a power line, a GND line, a signal line or the like. When the material of the pin 51 is a conductive material, the material may be copper (Cu) or the like. It is possible to provide Kovar plating, gold (Au) plating or the like on the surface of copper (Cu). It is possible to provide nickel (Ni) plating on the surface of copper (Cu) or the like, and further provide gold (Au) plating on the nickel (Ni) plating so as to coat the nickel plating.

The materials of the third and the fourth connectors 52 and 53 may be similar to the materials of the first and second connectors 42 and 43. The material can be similar to the solder material contained in the conductive balls 41. However, a conductive resin may be used instead of the solder material as the material of the third and fourth connectors 52 and 53. For example, the conductive resin is silver (Ag) paste, gold (Au) paste or the like.

As described, within the first embodiment, the electrode pads 22 including the first electrode pads 22a and the second electrode pads 22b arranged on the outer periphery relative to the first electrode pads 22a are formed below the semiconductor chip 20, and the third wiring layer (electrode pads) 37 including the third electrode pads 37a and the fourth electrode pads 37b arranged on the outer periphery relative to the third electrode pads 37a is formed on the wiring substrate 30. The second electrode pad 22b and the fourth electrode pad 37b are connected by the connecting unit 50 including the pin 51 and the third and fourth connectors 52 and 53.

Then, the area of the third connector 52 in contact with the one end side of the pin 51 and the area of the fourth connector 53 in contact with the other end side of the pin 51 become greater than the area of the first connector 42 in contact with the one end side of the conductive ball 41 and the area of the second connector 43 in contact with the other end side of the conductive ball 41. Said differently, the connection between the one end of the pin 51 and the third connector 52 and the connection between the other end of the pin 51 and the fourth connector 53 are firmer than the connection between the one end of the conductive ball 41 and the first connector 42 and the connection between the other end of the conductive ball 41 and the second connector 43.

As a result, if a large stress is applied to an outer peripheral side of the wiring substrate 30 by heat at a time of mounting the semiconductor chip 20 on the wiring substrate 30, the stress applied to the connecting unit 50 including the pin 51, the third connector 52 and the fourth connector 53 is relieved. Therefore, it is possible to reduce a probability of causing cracks or hiatuses which may be caused in the third and fourth connectors 52 and 53 by a conventional technique. Said differently, connection reliability between the semiconductor chip 20 and the wiring substrate 30 can be improved.

In order to make the connection between the one end of the pin 51 and the third connector 52 and the connection between the other end of the pin 51 and the fourth connector 53 firmer than the connection between the one end of the conductive ball 41 and the first connector 42 and the connection between the other end of the conductive ball 41 and the second connector 43, the diameters or widths of the second and fourth electrode pads 22b and 37b may be increased more than the diameters or widths of the first and third electrode pads 22a and 37a and the diameters or widths of the pin 51 may be increased. However, since the package density would be reduced, the diameters and widths of the second and fourth electrode pads 22b and 37b are preferably determined depending on the package density.

### Modified Example 1 of the First Embodiment

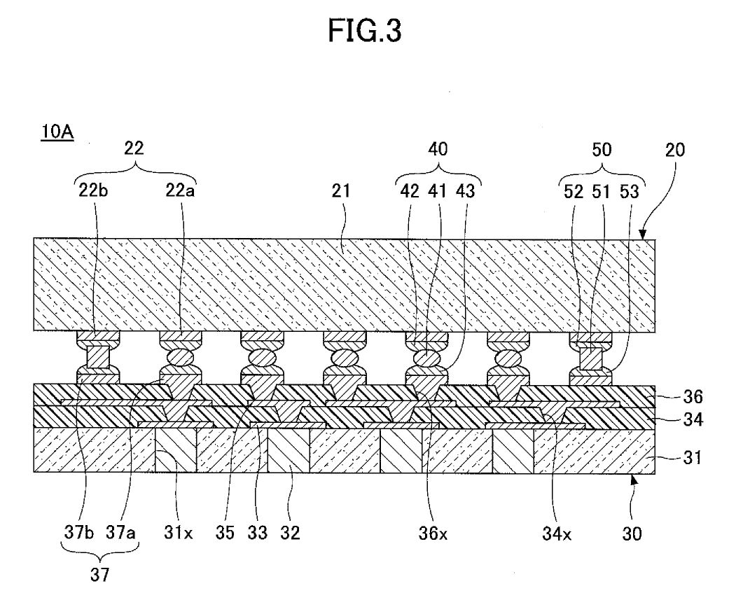

FIG. 3 is a cross-sectional view of a semiconductor package of a modified example 1 of the first embodiment. Referring to FIG. 3, a semiconductor package 10A differs from the semiconductor package 10 illustrated in FIG. 1 at a point that the second and fourth electrode pads 22b and 37b are not connected to another wiring layer or the like so that the second and fourth electrode pads 22b and 37b are electrically isolated (floated). In the modified example 1 of the first embodiment, explanation of constructional elements the same as those described in the above description of the first embodiment is omitted.

As described, the second and fourth electrode pads 22b and 37b may not be connected with the other wiring layer. Said differently, the pin 51 may not be used as a signal line or the like. The connecting unit 50 may be used only for a purpose of improving connection reliability between the semiconductor chip 20 and the wiring substrate 30. The semiconductor package 10A may perform a function similar to that of the semiconductor package 10.

In the semiconductor package 10A, the material of the pin 51 may be a conductive material such as copper (Cu) or an insulating material such as glass. However, if the material of the pin 51 is an insulating material such as glass, it is preferable to provide a process of improving wetability between the pin 51 and the third and fourth connectors 52 and 53.

### Modified Example 2 of the First Embodiment

Within the modified example 2 of the first embodiment, the material of the third and fourth connectors 52 and 53 to be connected with the pin 51 has a fusing point lower than the material of the first and second connectors 42 and 43. In the modified example 2 of the first embodiment, explanation of constructional elements the same as those described in the above description of the first embodiment is omitted.

In the semiconductor package of the modified example 2 of the first embodiment, the materials of the first and second connectors 42 and 43 are, for example, Sn—Ag. The structure of the semiconductor package of the modified example 2 is similar to that of the semiconductor package 10 and the drawing of the structure is omitted. The materials of the third and fourth connectors 52 and 53 may be Sn—Bi having fusing points of about 139° C. which is lower than the fusing point of Sn—Ag having a fusing point of 220° C. or greater. The materials of the first and second connectors 42 and 43 may be Sn—Sb having a fusing point of 250° C. or greater. The materials of the third and fourth connectors 52 and 53 may be Sn-37Pb having a fusing point of about 183° C.

The materials of the first and second connectors 42 and 43 may be Sn-90Pb having a fusing point of about 280° C. while the materials of the third and fourth connectors 52 and 53 may be Sn—In having a fusing point of about 117° C. The materials of the first and second connectors 42 and 43 may be Sn—Cu having a fusing point of about 227° C. while the materials of the third and fourth connectors 52 and 53 may be Sn—In having a fusing point of about 117° C.

The materials of the third and fourth connectors 52 and 53 connected to the pin 51 may have a fusing point lower than the materials of the first and second connectors 42 and 43. The construction is not limited to the above-described materials and combinations.

When the materials of the third and fourth connectors 52 and 53 connected to the pin 51 have the fusing point lower than the materials of the first and second connectors 42 and 43, connection reliability between the semiconductor chip 20 and the wiring substrate 30 can be further improved. The reason why the connection reliability can be improved when the materials of the third and fourth connectors 52 and 53 connected to the pin 51 have the fusing point lower than the materials of the first and second connectors 42 and 43 is described in detail while exemplifying a part of the manufacturing process of the semiconductor package of the modified example 2.

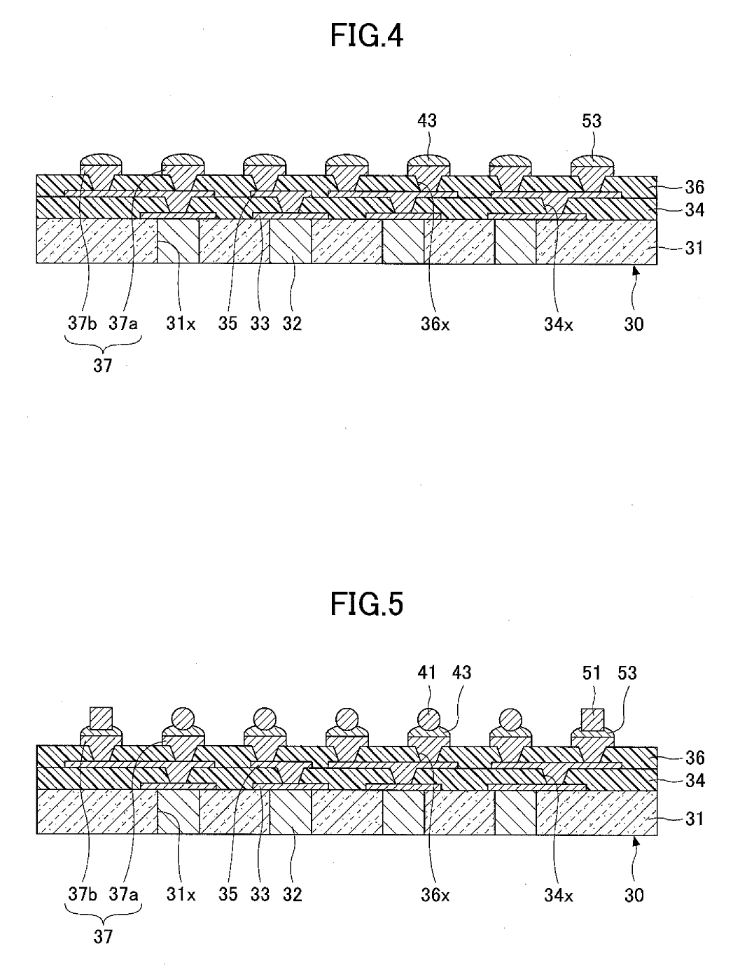

FIG. 4 to FIG. 6 illustrate a manufacturing process of the semiconductor package of the modified example 2 of the first embodiment. Referring to FIG. 4, a wiring substrate 30 is prepared, a second connector 43 is formed on a third electrode pad 37a, and a fourth connector 53 is formed on a fourth electrode pad 37b. For example, the wiring substrate 30 is formed as follows. Said differently, a through hole 31x is formed in a silicon plate by anisotropic etching, the through hole 31x is filled with copper (Cu) or the like by electro plating or the like to manufacture the substrate body 31. A first wiring layer 33 is formed by a semi-additive method on one surface of the substrate body 31.

Next, after forming a first insulating layer 34 covering the first wiring layer 33 on the one surface of the substrate body 31, a first via hole 34x, which penetrates through the first insulating layer 34 and from which the upper surface of the first wiring layer 33 is exposed, is formed by a laser processing method or the like. Further, a second wiring layer 35 connected to the first wiring layer 33 via the first via holes 34x is formed by a semi-additive method so that the second wiring layers 35 to be connected to the first wiring layers 33 are formed on the first insulating layer 34.

Said differently, after forming the second insulating layer 36 covering the second wiring layer 35 on the first insulating layer 34, a second via hole 36x is formed by a laser processing method or the like to penetrate the second insulating layer 36 and enable the upper surface of the second wiring layer 35 to be exposed to the outside. Further, a third wiring layer 37 to be connected to the second wiring layer 35 via the second via hole 36x is formed on the second insulating layer 36. For example, the material of the first wiring layer 33, the second wiring layer 35 and the third wiring layer 37 are copper (Cu) or the like. For example, the material of the first and second insulating layers 34 and 36 may be a thermosetting insulating resin containing an epoxy resin as a main material.

In order to form a second connector 43 on a third electrode pad 37a and to form a fourth connector 53 on a fourth electrode pad 37b, for example, a predetermined paste solder material (Sn—Bi or the like) having a fusing point lower than the predetermined solder material (Sn—Ag or the like) may be coated on the fourth electrode pad 37b.

Next, in the process illustrated in FIG. 5, a conductive ball 41 is arranged on the third electrode pad 37a of the wiring substrate 30 via the second connector 43, and a pin 51 is arranged on the fourth electrode pad 37b via the fourth connector 53. A device such as a ball mounter may be used to arrange the conductive ball 41 and the pin 51.

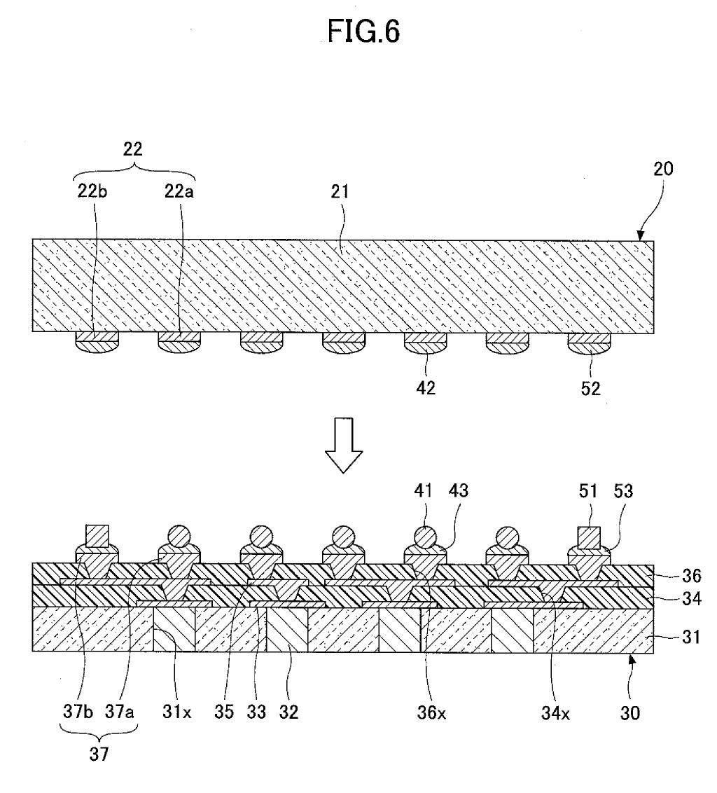

In the process illustrated in FIG. 6, a predetermined paste solder material (Sn—Ag or the like) is coated on the first electrode pad 22a to form a first connector 42, and a predetermined paste solder material (Sn—Bi or the like) having a fusing point lower than that of the predetermined solder material (Sn—Ag or the like) is coated on the second electrode pad 22b to form a third connector 52. The first connector 42, the conductive ball 41, the third connector 52 and the pin 51 are mutually positioned and placed in a reflow furnace. The solder material contained in the conductive ball 41, the first connector 42, the second connector 43, the third connector 52 and the fourth connector 53 are melted and thereafter cooled to harden. With this, the solder material contained in the conductive ball 41, the first connector 42, and the second connector 43 are alloyed to form a connecting unit 40. The third connector 52 and the fourth connector 53 are hardened to form a connecting portion 50. Thus, the semiconductor package of the modified example 2 of the first embodiment having the semiconductor chip 20 on the wiring substrate 30 is completed.

Meanwhile, great stress is applied on the outer peripheral side of the wiring substrate 30 because of displacement such as warpage and transformation mainly caused in the first and second insulating layers 34 and 36 of the wiring substrate 30 having a thermal expansion coefficient greater than that of the semiconductor chip 20 when the semiconductor chip 20 and the wiring substrate 30 are heated in the reflow furnace and then cooled. However, the outer peripheral side of the wiring substrate 30 is connected to the semiconductor chip 20 via the pin 51. Further, the third connector 52 (e.g., the solder material of Sn—Bi system) connecting the pin 51 to the semiconductor chip 20 and the fourth connector 53 (e.g., the solder material of Sn—Bi system) connecting the pin 51 to the wiring substrate 30 have the fusing point lower than that of the first and second connectors 42 and 43 (e.g., the solder material of Sn—Ag system).

While the semiconductor device is heated and thereafter cooled, the third and fourth connectors 52 and 53 are molten earlier than the first and second connectors 42 and 43. Therefore, if great displacement occurs especially on the outer periphery of the wiring substrate 30 in the process of heating in the reflow furnace and thereafter being cooled, since the third and fourth connectors 52 and 53 are already melted at a temperature higher than the fusing point of the third and fourth connectors 52 and 53, the pin 51 can move to follow (catch up) the displacement of the wiring substrate 30.

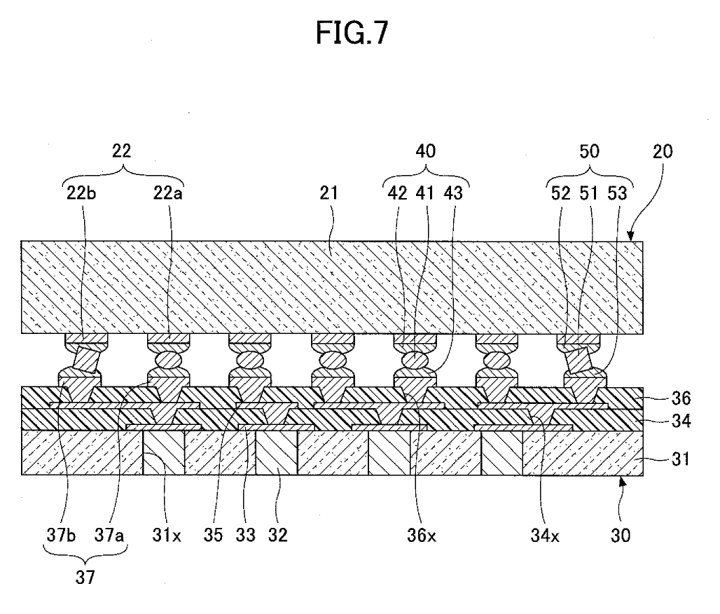

As a result, even if great displacement occurs especially on the outer peripheral side of the wiring substrate 30 as illustrated in FIG. 7, the third and fourth connectors 52 and 53 are hardened after the pin 51 is moved to follow (catch up) the displacement of the wiring substrate 30. Said differently, the second electrode pad 22b of the semiconductor chip 20 and the pin 51 are connected while relieving the stress applied to the third connector 52, and the fourth electrode pad 37b of the wiring substrate 30 and the pin 51 are connected while relieving the stress applied to the fourth connector 53. An example schematically illustrated in FIG. 7 is a state in which the third and fourth connectors 52 and 53 are hardened after the pin 51 is moved to follow (catch up) the displacement of the wiring substrate 30.

Referring to FIG. 7, the outer peripheral side of the wiring substrate 30 is displaced in an expanding direction. However, even if the outer peripheral side of the wiring substrate 30 is displaced in a contracting direction, the pin 51 can follow (catch up) the displacement of the wiring substrate 30.

With the modified example 2 of the first embodiment, effects similar to those in the first embodiment are obtainable. Further, the following effects are obtainable. Said differently, when the materials of the third and fourth connectors 52 and 53 connected to the pin 51 have lower fusing points than those of the materials of the first and second connectors 42 and 43, even if great displacement occurs especially on the outer peripheral side of the wiring substrate 30 in the processes of heating the semiconductor package 10 inside the reflow furnace and subsequently cooling the semiconductor package 10, the pin 51 can follow (catch up) the displacement of the wiring substrate 30 at a temperature higher than the fusing points of the materials of the third and fourth connectors 52 and 53. As a result, it is possible to relieve the stress applied to the third connector 52 and the fourth connector 53.

### Modified Example 3 of the First Embodiment

Within the modified example 3 of the first embodiment, a variation of the arrangement of the electrode pads is exemplified. In the modified example 3 of the first embodiment, explanation of constructional elements the same as those described in the above description of the first embodiment is omitted.

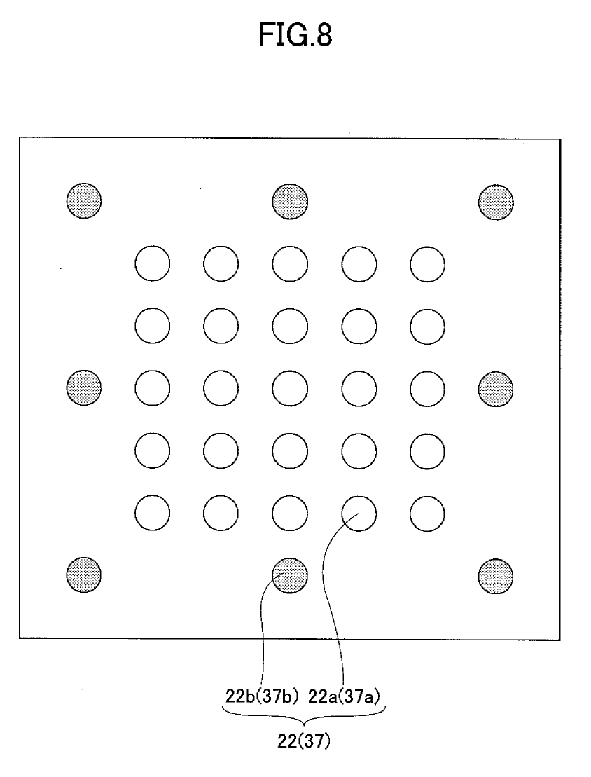

FIG. 8 to FIG. 10 are plan views of semiconductor chips and electrode pads of wiring substrates. Referring to FIG. 8 to FIG. 10, second electrode pads 22b and fourth electrode pads 37b are shaded like a satin finished surface for convenience. Referring to FIG. 8 to FIG. 10, pins 51 are positioned on the second electrode pads 22b and the fourth electrode pads 37b.

As illustrated in FIG. 8, the number of the second electrode pads 22b and the number of the fourth electrode pads 37b, which are respectively positioned outside the first electrode pads 22a and the third electrode pads 37a, may be arbitrarily determined. The arrangement may be other than those illustrated in FIG. 2 and FIG. 8. For example, the second electrode pads 22b and the fourth electrode pads 37b may be positioned only at four corners of the outermost periphery of the wiring substrate.

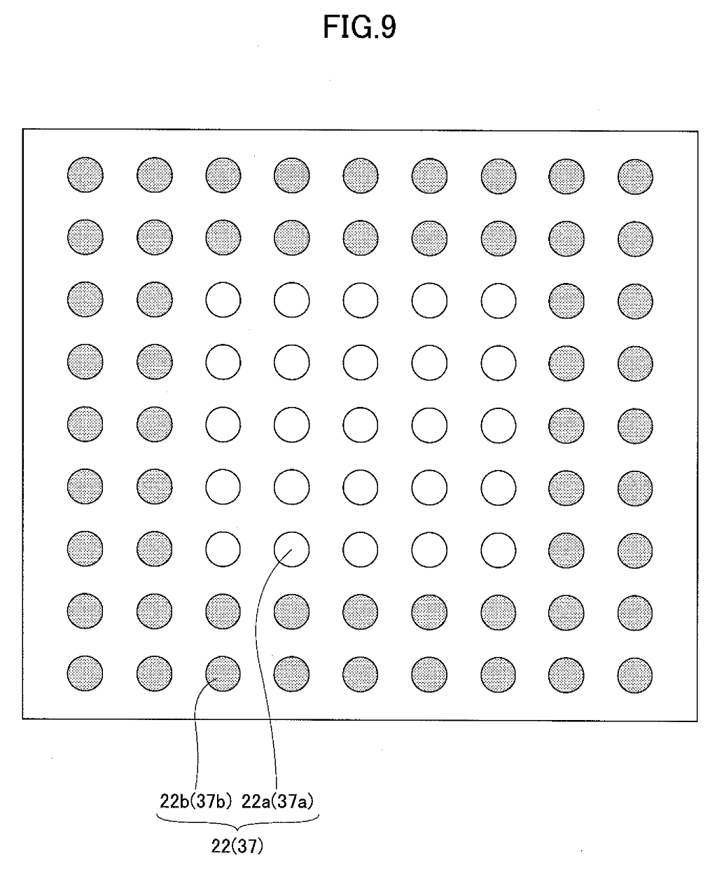

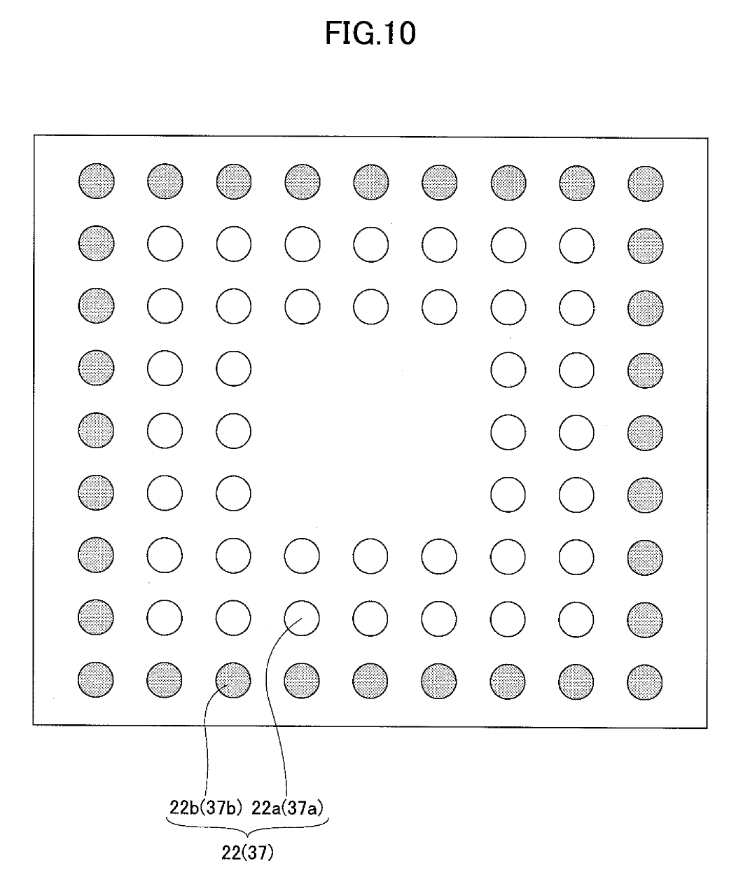

As illustrated in FIG. 9, the second electrode pads 22b positioned outside the first electrode pads 22a may be positioned like a double line along the outermost periphery of the wiring substrate instead of a single line illustrated in FIG. 8. The double line may be changed to a triple line. Further, as illustrated in FIG. 10, if the all electrode pads are positioned along the outermost periphery of the wiring substrate (hereinafter, this arrangement of the electrode pads is referred to as a peripheral arrangement), by positioning the second and fourth electrode pads 22b and 37b on an outer peripheral side of the first and third electrode pads 22a and 37a, it is possible to obtain an effect similar to the case where the electrode pads are positioned like the area array (hereinafter, this arrangement of the electrode pads is referred to as an area array arrangement) as illustrated in FIG. 2. Further, it is possible to transform the example illustrated in FIG. 10 to be the positions of the electrode pads illustrated in FIG. 8 and FIG. 9.

The mode of the positions of the electrode pads is not limited as long as the second electrode pads 22b and the fourth electrode pads 37b are positioned outside the first electrode pads 22a and the third electrode pads 37a.

Within the first embodiment and the modified examples 1-3 of the first embodiment, the wiring substrates 30 including the substrate bodies 31 made of silicon, glass, ceramic, resin or the like are exemplified. However, for example, the wiring substrate 30 of the semiconductor package 10 or 10A may be a coreless build-up wiring substrate without having the substrate body as a core. Further, a wiring substrate having wiring layers on both surfaces of the substrate body may be used.

As described, within the first embodiment and the modified examples 1-3 of the first embodiment, it is possible to provide a semiconductor package having high connection reliability between the semiconductor chip and the wiring substrate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor package comprising:
a semiconductor chip having a plurality of electrode pads; and
a wiring substrate having a plurality of electrode pads to mount the semiconductor chip on the wiring substrate,
wherein the plurality of electrode pads of the semiconductor chip include
a first electrode pad, and
a second electrode pad arranged on an outer periphery side of the first electrode pad,
wherein the plurality of electrode pads of the wiring substrate include
a third electrode pad, and
a fourth electrode pad arranged on an outer periphery side of the third electrode pad,
wherein the first electrode pad and the third electrode pad are connected via a first connecting portion,
wherein the second electrode pad and the fourth electrode pad are connected via a second connecting portion including a pin.

2. The semiconductor package according to claim 1,
wherein one end of the pin, the second electrode pad, another end of the pin, and the fourth electrode pad are connected by a first material,
wherein the first electrode pad and the third electrode pad are connected by a second material,
wherein a fusing point of the first material is lower than a fusing point of the second material.

3. The semiconductor package according to claim 1,
wherein the first electrode pad, the second electrode pad, the third electrode pad, and fourth electrode pad are circular in their plan views,
wherein diameters of the second and fourth electrode pads are greater than diameters of the first and third electrode pads.

4. The semiconductor package according to claim 1,
wherein the second electrode pad is positioned at an outermost periphery of the plurality of electrode pads included in the semiconductor chip, and the fourth electrode pad is positioned at an outermost periphery of the plurality of electrode pads included in the wiring substrate.

5. The semiconductor package according to claim 1,
wherein a main material of the semiconductor chip is silicon,
wherein the wiring substrate includes an insulating layer of which main material is a resin.

6. The semiconductor package according to claim 1,
wherein the second electrode pad is arranged on a side of the semiconductor chip outer than the first electrode pad and at a distance from the first electrode pad,
wherein the fourth electrode pad is arranged on a side of the wiring substrate outer than the third electrode pad and at a distance from the third electrode pad.
